(19) United States
(12) Patent Application Publication
(10) Pub. No.: US 2013/0089968 A1
(43) Pub. Date: Apr. 11, 2013

(54) METHOD FOR FINISHING SILICON ON INSULATOR SUBSTRATES

(71) Applicant: Alex Usenko, Painted Post, NY (US)

(72) Inventor: Alex Usenko, Painted Post, NY (US)

(21) Appl. No.: 13/805,143

(22) PCT Filed: Jun. 28, 2011
(86) PCT No.: PCT/US11/42168

§ 371 Date: Dec. 18, 2012

Related U.S. Application Data
(60) Provisional application No. 61/360,300, filed on Jun. 30, 2010.

(51) Int. Cl. H01L 21/3065

(52) U.S. Cl. CPC H01L 21/3065
USPC 438/458

(57) ABSTRACT

A process for finishing an as transferred layer on a semiconductor-on-insulator structure or a semiconductor-on-glass (or other insulator substrate) structure is provided by removing the damaged surface portion of a semiconductor layer while a leaving a smooth, finished semiconductor film on the glass. The damaged surface layer is treated with an oxygen plasma to oxidize the damaged layer and convert the damaged layer into an oxide layer. The oxide layer is then stripped in a wet bath, such as hydrofluoric acid bath, thereby removing the damaged portion of the semiconductor layer. The damaged layer may be an ion implantation damaged layer resulting from a thin film transfer processes used to make the semiconductor-on-insulator structure or the semiconductor-on-glass structure.

### CLAIMING BENEFIT OF PRIOR FILED U.S. APPLICATION

This application claims the benefit of priority under 35 U.S.C. §119 of U.S. Provisional Application Ser. No. 61/360300 filed on Jun. 30, 2010, entitled “METHOD FOR FINISHING SILICON ON INSULATOR SUBSTRATES”.

### BACKGROUND

The present invention relates generally to an improved finishing process for manufacturing semiconductor-on-insulator (SOI) substrates, more particularly for removing damaged surface portions of semiconductor films on SOI substrates produced using a thin film transfer process to provide an undamaged, smoothened surface.

To date, the semiconductor material most commonly used in semiconductor-on-insulator structures has been single crystalline silicon. Such structures have been referred to in the literature as silicon-on-insulator structures and the abbreviation “SOI” has been applied to such structures. Silicon-on-insulator technology is becoming increasingly important for high performance thin film transistors, solar cells, and displays. Silicon-on-insulator wafers consist of a thin layer of substantially single crystal silicon 0.01-1 microns in thickness on an insulating material. As used herein, SOI shall be construed more broadly to include a thin layer of material on insulating materials other than and including silicon.

Various ways of obtaining SOI structures include epitaxial growth of silicon on lattice matched substrates. An alternative process includes the bonding of a single crystal silicon wafer to another silicon wafer on which an oxide layer of SiO2 has been grown, followed by polishing or etching of the top wafer down to a layer of single crystal silicon having a thickness of several microns or greater. Further methods include “thin film transfer” methods in which ions of gases are implanted in a silicon donor wafer to create a weakened layer in the donor wafer for separation (exfoliation) of a thin silicon layer that is transferred and bonded to a handle or support wafer. The support wafer can be another silicon wafer, glass sheet, etc. The latter method of thin film transfer involving gas ion implantation is currently considered advantageous over the former methods for producing thin films on insulating handle substrates.

U.S. Pat. No. 5,374,564 discloses a thin film transfer and thermal bonding process for producing SOI substrates called “Smart Cut.” Thin film exfoliation and transfer by the hydrogen ion implantation method typically consists of the following steps. A thermal oxide film is grown on a single crystal silicon wafer (the donor wafer). The thermal oxide film becomes a buried insulator or barrier layer between the insulator/support wafer and the single crystal film layer in the resulting of SOI structure. Hydrogen ions are then implanted into the donor wafer to generate subsurface flaws. Helium ions may also be co-implanted with the Hydrogen ions. The implantation energy determines the depth at which the flaws are generated and the dosage determines flaw density at this depth. The donor wafer is then placed into contact and “pre-bonded” with another silicon support wafer (the insulating support, receiver or handle substrate or wafer) at room temperature to form a tentative bond between the donor wafer and the support wafer. The pre-bonded wafers are then heat-treated to about 600° C. to cause growth of the subsurface flaws resulting in separation of a thin layer or film of silicon from the donor wafer. The assembly is then heated to a temperature above 1000° C. to fully bond the silicon to the support wafer. This thin film transfer process forms an SOI structure with a thin film of silicon bonded to a silicon support wafer with an oxide insulator or barrier layer in between the film of silicon and the support wafer.

As described in U.S. Pat. No. 7,176,528, thin film transfer techniques have been applied more recently to SOI structures wherein the support substrate is a glass or glass ceramic sheet rather than another silicon wafer. This kind of structure is further referred to as silicon-on-glass (SiOG), although semiconductor materials other than silicon may be employed to form a semiconductor-on-glass (SOG) structure. Glass provides a cheaper handle substrate than silicon. Also, due to the transparent nature of the glass, the applications for SOI can be expanded to areas such as displays, image detectors, thermoelectric devices, photovoltaic devices, solar cells, photonic devices, etc, that may benefit from a transparent substrate.

The thin layer of semiconductor material (e.g., silicon) can be amorphous, polycrystalline, or of the single crystalline type. The amorphous and polycrystalline types of devices are less expensive than their single crystal counterparts, but they also exhibit lower electrical performance characteristics. The manufacturing processes for making SOI structures with amorphous or polycrystalline layers are relatively mature, and the performance of final products employing them is limited by the properties of the semiconductor material. In contrast to the amorphous and polycrystalline semiconductor materials, which are low quality semiconductors, single crystalline semiconductor material (such as silicon) is considered of relatively higher quality. Thus, the use of such higher quality single crystalline semiconductor materials will enable the manufacture of higher quality, higher performance devices.

In thin film transfer fabrication processes for fabricating SOI and SOG substrates, a semiconductor film or layer is exfoliated from a semiconductor donor wafer and bonded to an insulating support substrate, such as a silicon wafer or glass sheet. The surface of the exfoliated or “as transferred” semiconductor film is not perfectly smooth. The as transferred film typically has a surface roughness of about 10 nm. Moreover, the top portion of the as transferred film, for example, tens of nm deep into the as transferred film, has a large degree of crystal structure damage. This damage is a result of the high dose ion implantation and the heat induced exfoliation that are required to enable the film transfer process. During implantation, the ion species (e.g., hydrogen ions, or hydrogen and helium ions) are accelerated into the semiconductor crystal lattice. While moving through the crystal lattice, the ions displace semiconductor atoms from their regular locations in the lattice. The displaced semiconductor atoms are thus disruptions or damage in a properly ordered lattice, i.e. they are defects in or damage to the overall single crystalline media. Implanted ions eventually lose their kinetic energy and come to rest in the lattice. These ions are also defects in the crystal lattice, as they are not semiconductor atoms and they are not located in proper lattice locations. Therefore, after ion implantation, the donor silicon substrate will have hydrogen contaminated and displaced semiconductor atom damaged crystal regions within and around a range of depths. Following exfoliation of the silicon exfoliation layer, a portion of this contaminated and damaged region remains on the as transferred semiconductor film or layer. As a result, the surface of the as transferred semiconductor film exhibits excessive surface roughness and crystal damage. The surface roughness and crystal damage detrimentally effects the fabrication and performance of electrical device formed on or in the as transferred layer. Therefore, the rough and damage portion of the surface of the as transferred semiconductor layer or film must be removed and the surface must be smoothened.

There are several known surface removal and smoothing methods. Chemical-mechanical polishing (CMP) removal of damaged silicon is described in U.S. Pat. No. 3,841,031. The CMP polishing process involves holding and rotating a thin flat wafer of semiconductor material against a polishing surface under controlled pressure and temperature in the presence of a flow of polishing slurry. When polishing a relatively thin transferred semiconductor film on a relatively thick substrate, however, the polishing action degrades the thickness uniformity of the transferred film. Glass surface variations are in orders of microns, while the film to be smoothed is only fraction of a micron thick. Due to the relatively large size of the glass surface variations relative to the thickness of the thin film, some areas of the transferred film may get polished off completely with typical mechanical polishing processes forming holes in areas of the film, while other areas of the film may not be polished at all. A modified CMP method for smoothing silicon-on-glass uses a small computer-controlled polishing head, as is described, for example, in U.S. Pat. No. 7,312,154, in order to uniformly thin the film over high and low spots on the glass. This method is not advantageous, as it has a low throughput and volume manufacturing is not possible with this method.

Another problem with mechanical polishing processes is that they exhibit particularly poor results when rectangular SOI structures (e.g., those having sharp corners) are polished. Indeed, the aforementioned surface non-uniformities are amplified at the corners of the SOI structure compared with those at the center. Still further, when large SOI structures are contemplated (e.g., for photovoltaic applications), the resulting rectangular SOI structures are too large for typical polishing equipment (which are usually designed for the 300 mm standard wafer size). Cost is also an important consideration for commercial applications of SOI structures. The polishing process, however, is costly both in terms of time and money. The cost problem may be significantly exacerbated if non-conventional polishing machines are required to accommodate large SOI structure sizes.

Removal of the damaged portion of silicon film can also be performed by etching, either wet or dry. For wet etch of silicon, KOH can be used. For dry etch of silicon processing in CF4 plasma can be used. However, even though the etching techniques provide removal of the damaged silicon, they typically provide a conformal removal (e.g. the same thickness of material is removed from high spots on the surface as is removed from low spots on the surface), so the surface of an etched silicon film remains rough and no smoothening effect is achieved.

Isotropic etching of silicon would provide both damaged material removal and surface smoothening. Isotropic etching of silicon can be performed in, for example, so-called HNA solution, which is a mixture of hydrofluoric, nitric, and acetic acids. However, the HNA is highly dangerous and toxic, and therefore it does not fit well to large scale manufacturing. Also, a nitric oxide (laughing gas) is a byproduct of silicon etching in the HNA. The nitric oxide is highly aggressive and toxic, which make it not well suited for the large scale manufacturing.

Also, in silicon-on-insulator (SOI) technology, thermal oxidation/strip cycles have been used to obtain SOI wafers with a very thin top silicon film, much thinner than the as-transferred silicon film. Thermal oxidation is a process requiring temperatures 900° C. or higher. This cannot be used for SiOG, as most glasses can only withstand temperatures up to about 600° C.

Further steps in the process of fabricating SOI substrates, such as bonding, exfoliation, annealing and/or polishing, may result in partial or total removal of implantation-induced crystal damage. Bonding and exfoliation steps are usually performed at elevated temperatures, which drive any residual hydrogen ions out of the lattice due to diffusion. In order to completely heal the implant-induced damaged by heating (e.g., annealing), the crystal has to be heated to a temperature approaching the melting temperature of the crystal semiconductor material. For silicon, the melting temperature is 1412° C., and heating to about 1100° C. is required to almost completely heal the post-implantation crystal damage. During the process of fabricating a silicon-on-glass device, annealing to temperatures above about 600° C. is prohibited because most glasses can only withstand such high temperatures

Melting and re-crystallization of the exfoliated semiconductor layer using excimer laser annealing is described in international publication WO/2007/142911. The excimer laser beam melts a top portion of the semiconductor layer while maintaining the glass substrate at a cooler temperature. This method results in poorer electrical characteristics within the annealed semiconductor material because the melted part of the single crystalline material solidifies too fast. In a regular Czochralski method of silicon growth, the rate of growth is around 1 millimeter per minute. In contrast, the re-growth rate of silicon melted and re-crystallized via an excimer laser is about 10E14 times faster. The relatively slow growth rate of the Czochralski method allows a nearly ideal crystal lattice to grow. At faster growth rates, there is not enough time for individual silicon atoms to diffuse to proper positions. Many silicon atoms are thus frozen at irregular locations, which means that they are structural defects in the newly formed lattice.

In commonly owned U.S. patent application Ser. No. 12/391,340 filed on Feb. 42, 1009, entitled Semiconductor on Insulator Made Using Improved Defect Healing Process, the damaged, single crystalline silicon layer of a silicon-on-glass structure is implanted with silicon in a dose and at an energy sufficient to amorphize an upper, damaged portion of the single crystal silicon material, but not sufficient to amorphize the entire single crystal silicon layer. The pre-implanted substrates are then annealed at a temperature in a range between about 550° C. and 650° C. to transform the amorphous layer into a single crystalline layer. The lower, non-amorphized portion of the silicon layer serves as a seed for solid phase epitaxial re-growth of the single crystal material. This method reduces the amount of structural defects in the damaged portion of silicon film, but it does not improve surface roughness much. Thus, only one of two required actions of film finishing is accomplished with this method.

For polysilicon annealing, the excimer laser technique is effective, as the polysilicon can be approximated as a crystal with a very high level of structural defects. In an SOI obtained by exfoliation of a single crystal semiconductor layer, however, the initial number of defects of the semiconductor material is not as high as in polysilicon. While the excimer laser annealing technique may heal some or all of the initial defects in the semiconductor material, it introduces new defects in about the same concentration as before the annealing, or even higher. Thus, the excimer laser annealing technique results in only a marginal improvement in the electrical properties of the exfoliated semiconductor layer.

An additional problem with laser annealing is that the melted semiconductor material, such as silicon, is significantly denser than crystalline silicon (2.33 and 2.57 g/cm3 respectively). When the melted silicon solidifies after the excimer laser scan, the difference between the respective densities results in a characteristic, periodic fluctuation in the thickness of the re-melted silicon. Thus, the excimer laser annealed films are inherently non-smooth, which is a disadvantage.

For the reasons discussed above, none of the aforementioned techniques and processes for removing or otherwise correcting for damage to the semiconductor lattice structure has been satisfactory in the context of manufacturing SOG structures. Thus, there is a need in the art for an improved and economical process for finishing SOI structures, and in particular SOG structures, in order to both (1) remove the damaged portion in the surface of the as transferred semiconductor layer created during ion implantation and (2) smoothen (or finish) the surface of the as transferred semiconductor layer.

### SUMMARY

One or more features disclosed herein include removal of the ion implant damaged surface portion or layer of the exfoliated semiconductor layer obtained using a thin film transfer process or other layer formation process. The damaged layer is removed in a manner that will not degrade, or otherwise damage a glass substrate supporting the semiconductor layer. In accordance with one or more embodiments disclosed herein, methods of forming a semiconductor on glass structure, include: subjecting the as transferred semiconductor film to an oxygen plasma treatment to oxidize the ion implant damaged layer, region or portion of the exfoliated semiconductor layer; and then stripping the oxidized layer in a wet bath, such as with a hydrofluoric acid solution, thereby removing the damaged portion of the as transferred exfoliated semiconductor layer.

According to an embodiment hereof, the method of forming a semiconductor on glass structure may include the steps of: subjecting an implantation surface of a semiconductor donor wafer to an ion implantation process to create an exfoliation layer of the semiconductor donor wafer; bonding the implantation surface of the exfoliation layer to a glass or glass-ceramic substrate; separating the exfoliation layer from the semiconductor donor wafer, thereby exposing a rough, ion implantation damaged surface layer on the exfoliation layer; subjecting the rough, damaged surface layer to oxygen plasma to oxidize the damaged surface layer and convert the damaged layer to an oxide layer; and stripping the oxide layer, thereby removing the damaged layer and leaving a smoothened, finished surface on the exfoliation layer bonded to the glass or glass ceramic substrate.

The exfoliation layer may be oxidized and stripped to a depth sufficient to thin the exfoliation layer substantially to a desired final or finished thickness in a single oxidize/strip step or in multiple oxidize/strip steps or cycles.

The exfoliation layer may be oxidized and stripped to a depth sufficient to remove the entire damaged layer in a single oxidize/strip step. Alternatively, multiple oxidize/strip steps or cycles may be employed to remove the damaged layer bit by bit.

The oxygen plasma processing parameters is in a range sufficient to oxidize an upper portion of exfoliation layer closest to the at least one cleaved surface, while not oxidizing a lower portion of the semiconductor material farther from the at least one cleaved surface.

The oxygen plasma treatment may be conducted in a plasma generated at a frequency of 1 MHz or lower, from 1 MHz to 1 kHz, or about 30 kHz or lower.

The semiconductor donor wafer may be formed of silicon (Si), germanium-doped silicon (SiGe), silicon carbide (SiC), germanium (Ge), gallium arsenide (GaAs), gallium nitride (GaN), GaP, or InP.

According to other embodiments hereof, a method is provided that includes forming a semiconductor on glass structure, including the steps of: subjecting an implantation surface of a semiconductor donor wafer to an ion implantation process to create an exfoliation layer of the semiconductor donor wafer; bonding the implantation surface of the exfoliation layer to a glass substrate; separating the exfoliation layer from the semiconductor donor wafer, thereby exposing an ion implantation damaged layer on the surface of the exfoliation layer; characterized by the steps of: the subjecting the exposed damaged layer to oxygen plasma to oxidize the exposed damaged layer and convert at least a portion of the exposed damaged layer to an oxide layer; and stripping the oxide layer, thereby removing at least a portion of the damaged layer.

The oxygen plasma processing parameters may be one of: in a range sufficient to oxidize at least a portion of the exposed damaged layer, while leaving at least a portion of an undamaged lower portion of the semiconductor exfoliation layer unoxidized; in a range sufficient to oxidize the exposed damaged layer to a depth that is at least equal to or slightly greater than a depth of the damaged layer; or selected to oxidize the exposed damaged layer to a depth in a range from about 10 nm to about 20 nm.

The plasma treatment may be conducted in a plasma generated at one of: a frequency of 1 MHz or lower; a frequency of from 1 MHz to 1 kHz; a frequency of about 30 kHz or lower; a frequency of about 13.56 MHz; or a frequency of about 30 kHz.

The plasma treatment may be conducted in a direct current plasma (zero frequency) with at least one of: a power in a range from about 1 Watt/cm² to about 50 Watts/cm²; a pressure in a range from about 0.3 mTorr to about 300 mTorr; and for a time in a range from about 0.5 minutes to about 50 minutes.

The semiconductor donor wafer may be formed of a material selected from the group consisting of: gallium nitride (GaN), silicon (Si), germanium-doped silicon (SiGe), silicon carbide (SiC), germanium (Ge), gallium arsenide (GaAs), GaP, and InP.

A portion of the damaged layer may remain on the exfoliation layer following oxygen plasma oxidizing and stripping steps, and the process may further include the steps of: the subjecting the remaining portion of the damaged layer to oxygen plasma to oxidize the remaining portion of the damaged layer and convert at least a portion of the remaining portion of the exposed damaged layer to an oxide layer; and stripping the oxide layer, thereby removing at least a portion of the remaining portion of the damaged layer. The oxygen plasma processing parameters when oxidizing the remaining portion of the damaged layer may be in a range sufficient to oxidize the remaining portion of the damaged layer to a depth that is at least equal to or slightly greater than a depth of the remaining portion of the damaged layer.

According to other embodiments hereof, a method is provided that includes the steps of providing a semiconductor donor structure having weakened damaged layer therein defining an exfoliation layer between the damaged layer and a bonding surface of the donor wafer; bonding the bonding surface of the donor semiconductor structure to an insulating support substrate; separating the exfoliation layer, bonded to the support substrate, from the donor semiconductor structure along the damaged layer, thereby exposing a damaged surface on the separated exfoliation layer, the damaged surface including damage to a first depth below the damaged surface; subjecting the at least one damaged surface to an oxygen plasma treatment to oxidize the damages surface to at least a second depth of the semiconductor material; and removing the oxide layer, thereby removing the damaged layer from the semiconductor layer. The insulating support substrate is a glass or glass-ceramic substrate.

Other aspects, features, advantages, etc. will become apparent to one skilled in the art when the description herein is taken in conjunction with the accompanying drawings.

### BRIEF DESCRIPTION OF THE DRAWINGS

The accompanying drawings are included to provide a further understanding, and are incorporated in and constitute a part of this specification. The drawings illustrate one or more embodiment(s), and together with the description serve to explain principles and operation of the various embodiments.

FIG. 1 is a schematic side view of an SOG substrate fabricated using a conventional thin film transfer processes;

FIG. 2 is a schematic side view of a semiconductor donor wafer being implanted with ions in a conventional thin film transfer processes;

FIG. 3 is a schematic side view of an implanted semiconductor donor wafer being bonded to a glass support or handle substrate in a conventional thin film transfer processes;

FIG. 4 is a schematic side view of the remaining portion of the semiconductor donor wafer separated from the semiconductor exfoliation layer bonded to the glass substrate in a conventional thin film transfer processes;

FIG. 5 is a schematic side view of an SOG substrate fabricated using a conventional thin film transfer processes;

FIG. 6 is a schematic side view of the surface of the SOG substrate undergoing an oxygen plasma oxidation/conversion treatment according to one embodiment described herein;

FIG. 7 is a schematic side view of a finished SOG substrate produced as described herein;

FIG. 8 is a plot showing the thickness of the converted oxidized layer in the exfoliation layer as a function of oxygen plasma treatment time;

FIG. 9 is a plot showing the thickness of the converted oxidized layer in the exfoliation layer as a function of oxygen plasma treatment pressure;

FIG. 10 is a plot showing the thickness of the converted oxidized layer in the exfoliation layer as a function of oxygen plasma treatment power;

FIG. 11 is a plot illustrating the oxidation growth kinetics in a process in accordance with an embodiment hereof;

FIG. 12 is a plot showing the average surface roughness of the as transferred surface of various test samples before and after processing in accordance with an embodiment hereof in comparison to a control sample; and

FIG. 13 is a plot showing peak-to-valley surface roughness of the as transferred surface of various test samples before and after processing in accordance with an embodiment hereof.

### DETAILED DESCRIPTION

Although the features, aspects and embodiments disclosed herein may be discussed in relation to silicon-on glass (SiOG) structures and the manufacture of SiOG structures, skilled artisans will understand that this disclosure need not be and is not limited to SiOG structures. Indeed, the broadest protectable features and aspects disclosed herein are applicable to any process in which thin film transfer or other techniques are employed to transfer and bond a thin film of a semiconductor material on a glass or glass-ceramic support or handle substrate to produce a semiconductor-on-glass (SOG) structure. For ease of presentation, however, the disclosure herein is primarily made in relation to the manufacture of SiOG structures. The specific references made herein to SiOG structures are to facilitate the explanation of the disclosed embodiments and are not intended to, and should not be interpreted as, limiting the scope of the claims in any way to SiOG substrates. The processes described for the fabrication of SiOG substrates are equally applicable the manufacture of other SOG substrates and to semiconductor-on-insulator (SOI) substrates where the insulator substrate is another semiconductor substrate such as a silicon wafer. The SOI, SiOG and SOG abbreviations as used herein should be viewed as referring not just to semiconductor-on-glass (SOG) structures, but also to semiconductor-on-insulator (SOI) structures in general, including, but not limited to, single crystal silicon-on-silicon (SOI) structures.

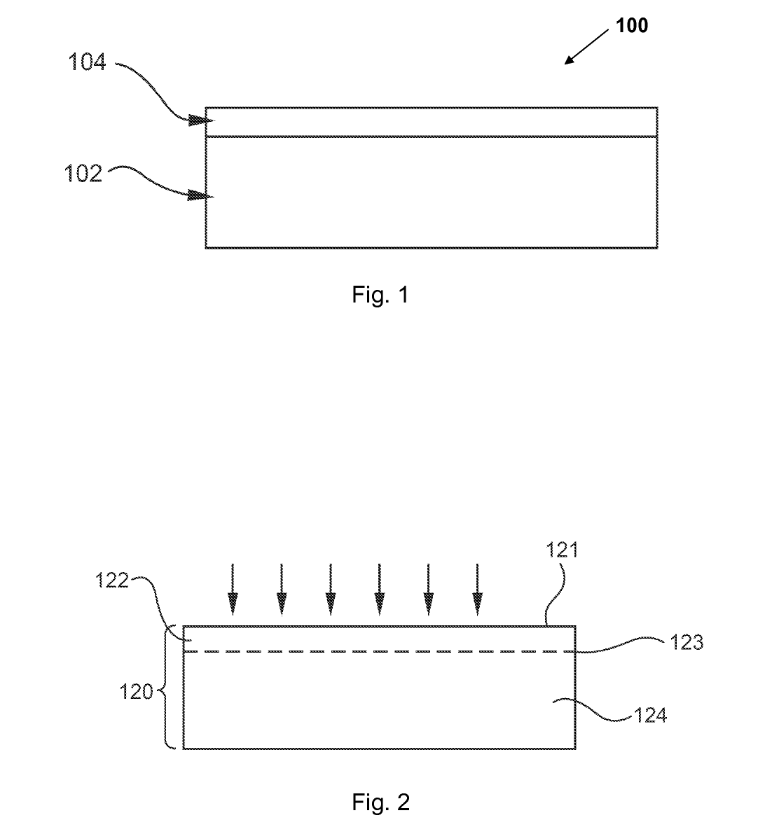

With reference to the drawings, wherein like numerals indicate like elements, there is schematically shown in FIG. 1 an SOG structure 100 in accordance with one or more embodiments disclosed herein. The SOG structure 100 may include a glass substrate 102 and a semiconductor layer 104. The SOG structure 100 has suitable uses in connection with fabricating thin film transistors (TFTs), e.g., for display applications, including organic light-emitting diode (OLED) displays and liquid crystal displays (LCDs), integrated circuits, photovoltaic devices, solar cells, thermoelectric devices, etc.

The semiconductor material of the layer 104 may be in the form of a substantially single-crystal material. The term “substantially” is used in describing the layer 104 to take account of the fact that semiconductor materials normally contain at least some internal or surface defects either inherently or purposely added, such as lattice defects. The term substantially also reflects the fact that certain dopants may distort or otherwise affect the crystal structure of the semiconductor material.

For the purposes of discussion, it is assumed that the semiconductor layer 104 is formed from silicon. It is understood, however, that the semiconductor material may be a silicon-based semiconductor or any other type of semiconductor, such as III-V, II-IV, II-IV-V, etc. classes of semiconductors.

By way of example only, regular round 300 mm prime grade silicon wafers may be chosen for use as donor wafers or substrates 120 for the fabrication of SiOG structures or substrates. The donor wafers may have <001> crystalline orientation and 8-12 Ohm/cm resistivity, and be Cz grown, p-type, boron doped wafers. Crystal Originated Particle (COP) free wafers may be chosen, because the COPs might obstruct the film transfer process or disturb transistor operation. Alternatively, standard 300 mm size low doped p-type with boron concentration between 10E15 cm-3 and 10E16 cm-3 wafers manufactured by MEMC, Optia type (perfect silicon+magic denuded zone) may be used. Doping type and level in the wafers may be chosen to obtain desirable threshold voltages in eventual transistors to subsequently be made on the SiOG substrates. The largest available wafer size 300 mm may be chosen, because this will allow economical SiOG mass production. 180×230 mm rectangular donor wafers or donor tiles may be cut from the initially round wafers. The donor tile edges may be processed with a grinding tool, lasers, or other known techniques, in order to profile the edges and obtain a round or chamfered profile similar to SEMI standard edge profile. Other required machining steps, such as corner chamfering or rounding and surface polishing, may also be performed. Such donor wafer substrates or tiles may also be used to fabricate rectangular SOG structures in accordance with a further embodiment hereof. Alternatively, the donor wafer may be left as round wafers and be used to transfer round semiconductor films/exfoliation layers to square or round glass or glass ceramic substrates.

The bonding surface of the donor wafers may optionally be coated with a stiffener film, as described in contemporaneously filed, co-pending U.S. patent application Ser. No. 12/827,582 entitled Silicon On Glass Substrate With Stiffening Layer and Process of Making the Same.

The glass substrate 102 may be formed from a glass, glass-ceramic, oxide glass or an oxide glass-ceramic. Although not required, the embodiments described herein may include an oxide glass or glass-ceramic exhibiting a strain point of less than about 1,000 degrees C. As is conventional in the glass making art, the strain point is the temperature at which the glass or glass-ceramic has a viscosity of 10^{14.6} poise (10^{13.6} Pa.s). As between oxide glasses and oxide glass-ceramics, the glasses may have the advantage of being simpler to manufacture, thus making them more widely available and less expensive. By way of example, a glass substrate may be formed from glass containing alkaline earth ions, such as Gen 2 size substrates made of Corning Incorporated glass composition no. 1737, Corning Incorporated Eagle 2000™ glass, or Corning Incorporated Eagle XG™ glass. These Corning Incorporated fusion formed glasses have particular use in, for example, the production of liquid crystal displays. Moreover, the low surface roughness of these glasses that is required for fabrication of liquid crystal display backplanes on the glass is also advantageous for effective bonding as described herein. Eagle glass is also free from heavy metals and other impurities, such as arsenic, antimony, barium, that can adversely affect the silicon exfoliation/device layer. Being designed for the manufacture of flat panel displays with polysilicon thin film transistors, Corning® Eagle glass has a carefully adjusted coefficient of thermal expansion (CTE) that substantially matches the CTE of silicon, e.g. a Eagle glass has a CTE of 3.18×10−6 C-1 at 400° C. and silicon has a CTE of 3.2538×10-6 at 400° C. Eagle glass also has a relatively high strain point of 666° C., which is higher than the temperature needed to trigger exfoliation (typically around 500° C.). These two features, e.g. ability to survive exfoliation temperatures and CTE match with silicon, make Corning Eagle glass a good choice as a substrate for silicon layer transfer and bonding.

The glass substrate 102 may have a thickness in the range of about 0.1 mm to about 10 mm, such as in the range of about 0.5 mm to about 3 mm. In general, the glass substrate 102 should be thick enough to support the semiconductor layer 104 through the bonding process steps, as well as subsequent processing performed on the SiOG structure 100. Although there is no theoretical upper limit on the thickness of the glass substrate 102, a thickness beyond that needed for the support function or that desired for the ultimate SOG structure 100 might not be advantageous since the greater the thickness of the glass substrate 102, the more difficult it will be to accomplish at least some of the process steps in forming the SOG structure 100.

The glass substrates may be rectangular in shape and may be large enough to hold several donor wafers arrayed on the bonding surface of the glass. In which case, at least one donor wafer-glass assembly, that includes a plurality of donor wafers arrayed on the surface of a single glass sheet, may be placed into the furnace/bonder for film transfer. The donor wafers may be round semiconductor donor wafers or they may be rectangular semiconductor donor wafers/tiles. The resulting SOG product would comprise a single glass sheet with a plurality of round or rectangular silicon films bonded thereto.

Reference is now made to FIGS. 2-7, which schematically illustrate intermediate structures that may be formed in carrying out the process of manufacturing the SOG structure 100 of FIG. 1 in accordance with one or more aspects of the present invention.

Turning first to FIG. 2, an implantation surface 121 of a semiconductor donor wafer 120 is prepared, such as by polishing, cleaning, etc. to produce a relatively flat and uniform implantation surface 121 suitable for bonding to the glass or glass-ceramic substrate 102. In preparation for bonding, the bonding surface 121 of the donor wafer 120 is first cleaned to remove dust and contaminants and is activated. The donor wafer may be cleaned by processing the donor wafer in an RCA solution and drying. Activation is the formation of adsorbed hydroxyl groups and further adsorbed water molecules on the surface of the donor wafer, which may be done by performing a plasma treatment on the bonding surface. For the purposes of discussion, the semiconductor donor wafer 120 may be a substantially single crystal Si wafer, although as discussed above any other suitable semiconductor conductor material may be employed.

The glass sheets 102, or other material substrates to be used as the support substrate, are also cleaned to remove dust and contaminants and activated in preparation for bonding. A wet ammonia process may be used to clean the glass, render the surface of the glass hydrophilic, and terminate the glass surface with hydroxyl groups (i.e. activate the surface of the glass) for enhanced bonding of the glass 102 to the bonding surface 121 of the donor wafer 120. The glass sheets may then be rinsed in de-ionized water and dried. One of skill in the art will understand how to formulate suitable washing and activating solutions and procedures for the donor wafers and the glass (or other material) support substrates.

An exfoliation layer 122 is created in the donor wafer 120 by subjecting the implantation surface 121 to one or more ion implantation processes to create a weakened region or layer 123 below the implantation surface 121 of the semiconductor donor wafer 120. Although the embodiments of the present invention are not limited to any particular method of forming the exfoliation layer 122, Hydrogen ions (such as H⁻ and/or H²⁺ ions) may be implanted (as indicated by the arrows in FIG. 2) into the bonding surface 121 of the donor wafer 120 to a desired depth to form a damage/weakened zone or layer 123 in the silicon donor wafer 120. Co-implantation of Helium ions and Hydrogen ions into the bonding surface 121 of the donor wafer, may also be employed to form the weakened layer 123. An exfoliation layer 122 is thereby defined in the donor wafer 120 between the weakened layer 123 and the bonding surface 121 of the donor wafer. As is well understood in the art, the ion implantation energy and density may be adjusted to achieve a desired thickness of the exfoliation layer 122, such as between about 300-500 nm, although any reasonable thickness may be achieved, and to accommodate for any additional layers, such as oxide barrier or Si₃N₄ stiffening layers, that may be on the bonding surface of the donor wafer. Appropriate implantation energies for a desired thickness of transferred film (e.g. implantation depth) can be calculated using a SRIM simulation tool. For example, for H²⁺ ions implanted at an energy of 60 keV through a 100 nm Si₃N₄ barrier layer into the donor wafer 120 will form an exfoliation layer 122, including the Si₃N₄ barrier layer.

Regardless of the nature of the implanted ion species, the effect of implantation on the exfoliation layer 122 is the displacement of atoms in the crystal lattice from their regular locations. When the atom in the lattice is hit by an ion, the atom is forced out of position and a primary defect, a vacancy and an interstitial atom, is created, which is called a Frenkel's pair. If the implantation is performed near room temperature, the components of the primary defect move and create many types of secondary defects, such as vacancy clusters, etc. The vacancy clusters may be annealed at temperatures exceeding 900° C.; however, as discussed above, to completely heal implant-induced damaged by annealing, the exfoliation layer 122 would have to be heated to a temperature approaching the melting temperature of the semiconductor material, which would warp or even melt the glass substrate 102 (which is added later in the manufacturing process). If annealing was carried out at a lower temperature, such as 600° C., the exfoliation layer 122 would still contain defects, such as the aforementioned vacancy clusters and other impurity-vacancy clusters. Most of these types of defects are electrically active, and serve as traps for major carriers in the semiconductor lattice. Therefore, the concentration of free carriers in the exfoliation layer 122 is lower when post-implantation defects are present. The electrical resistivity of defect laden semiconductor material is also worsened compared to defect-free semiconductor material. A process for removing the implantation-induced defects will be discussed later in this description.

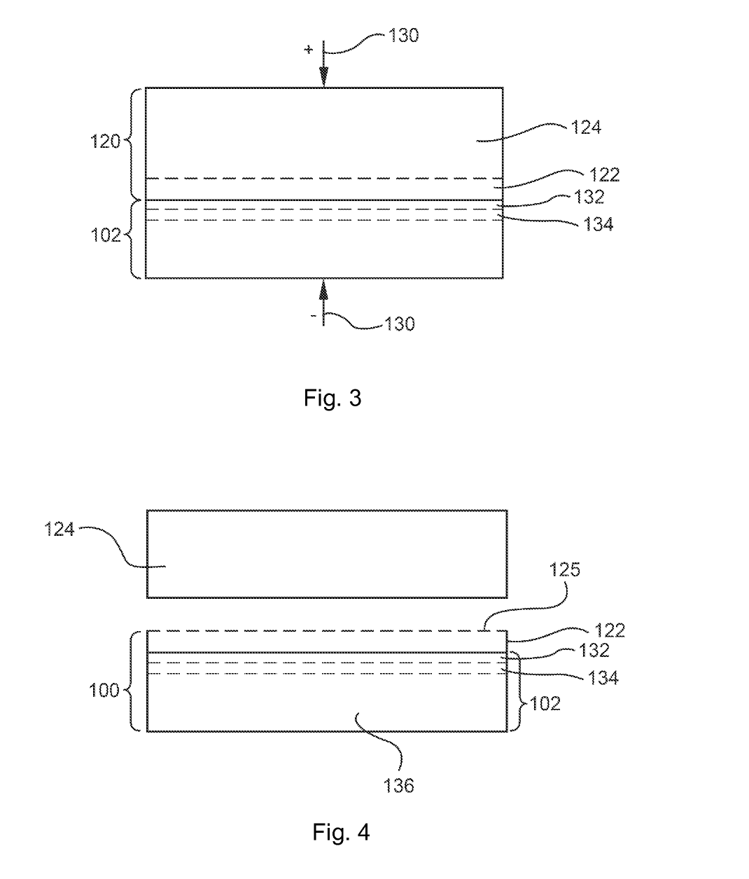

With reference now to FIG. 3, the bonding surface 121 of the exfoliation layer 122 (with the barrier layer 142 thereon) is then pre-bonded to the glass support substrate 102. The glass and the donor wafer, especially in the case of rectangular donor wafers or tiles, may be pre-bonded by initially contacting them at one edge, thereby initiating a bonding wave at the one edge, and propagating the bonding wave across the donor wafer and support substrate to establish a void free pre-bond. Alternatively, pre-bonding may be performed by mating the glass substrates and donor tiles or wafers at desired point and applying pressure at the desired point of the contacted pair to initiate a bonding wave. The bonding wave proceeds across entire contacted surfaces in about 10 to 20 seconds. The resulting intermediate structure is thus a stack including the exfoliation layer 122 of the semiconductor donor wafer 120, a remaining portion 124 of the donor wafer 120, and the glass support substrate 102.

The glass substrate 102 may now be bonded to the exfoliation layer 122 using an electrolysis process (also referred to herein as an anodic bonding process) by applying a voltage across the intermediate assembly, as illustrated by the + and − symbols in FIG. 3, while heating the assembly. Alternatively, bonding is achieved by a thermal bonding process, such as a “Smart Cut” thermal bonding process. A basis for a suitable anodic bonding process may be found in U.S. Pat. No. 7,176,528, the entire disclosure of which is hereby incorporated herein by reference. Portions of this process are discussed below. A basis for a suitable Smart Cut thermal bonding process may be found in U.S. Pat. No. 5,374,564, the entire disclosure of which is hereby incorporated herein by reference.

According to one embodiment disclosed herein, the pre-bonded glass-donor wafer assemblies are placed in a furnace/bonder for bonding and film transfer/exfoliation. The glass-donor wafer assemblies may be placed horizontally in a furnace or bonder in order to prevent the remaining portions of the donor wafers from sliding on the newly transferred exfoliation layer following exfoliation and scratching the newly created silicon film 122 on the glass substrate substrates 102. The glass-donor wafer assemblies may be arranged in the furnace with the silicon donor wafer 120 on the bottom, downward facing side of the glass support substrate 102. With this arrangement, the remaining portion 124 of the silicon donor wafer may be allowed to simply drop down away from the newly exfoliated and transferred exfoliation layer 122 following exfoliation or cleaving of the exfoliation layer 122. Scratching of the newly created silicon film (the exfoliation layer) on the glass may thus be prevented. Alternatively, the glass-donor wafer assemblies may be placed horizontally in the furnace with the donor wafer on top of the glass substrate. In which case, the remaining portion 124 of the donor wafer must be carefully lifted from the glass substrate to avoid scratching the newly exfoliated silicon film 122 on the glass.

Once the pre-bonded glass-silicon assembly is loaded into the furnace, the furnace may be heated to 100-200° C. and maintained at that temperature for about 1 hour, for example, during a first heating step. This first heating step increases the bonding strength between the silicon and the glass thus eventually improving layer transfer yield. The temperature may then be ramped at slow rate of about 10° C. per minute up to as high as 600° C. to cause exfoliation during a second heating step. Ramping the temperature too quickly may result in temperature gradients that cause mechanical stresses. The stresses may cause various defects in the SiOG substrates as canyons, sheet warpage, etc. When temperature reaches about 300 to 500° C., the exfoliation layer 122 separates or exfoliates from the remaining portion 124 of the semiconductor donor wafer 120. The result is an SOG structure 100, including a glass substrate 102 with the relatively thin exfoliation layer 122 (formed of semiconductor material of the semiconductor donor wafer 120) bonded thereto. The separation may be accomplished via fracture of the exfoliation layer 122 due to thermal stresses. Alternatively or in addition, mechanical stresses such as water jet cutting, localized heating, or chemical etching may be used to facilitate the separation.

By way of example, the temperature during the second heating step may be within about ±350° C. of a strain point of the glass substrate 102, more particularly between about −250° C. and 0° C. of the strain point, and/or between about −100° C. and −50° C. of the strain point. Depending on the type of glass, such temperature may be in the range of about 500-600° C. One skilled in the art can properly design furnace processing for exfoliation as it is described herein and as described, for example, in U.S. Pat. Nos. 7,176,528 and 5,374,564, and U.S. published patent application Nos. 2007/0246450 and 2007/0249139.

After exfoliation, the newly formed SOG substrate 100 and the remaining portion of the donor wafers or tiles may optionally be annealed, for example, by increasing the temperature to about 600° C. in and thermally treating the substrate 100 in an inert atmosphere for about 12 hours. During this annealing step the implantation-induced defects are partially annealed. It is not possible to anneal all the defects. Some of the defects are stable at temperature above 600° C., whereas Eagle glass and other glasses can only withstand temperatures up to about 600° C. The non-annealed defects are typically electrically active and adversely affect the electrical properties of the SiOG structure. Also, during this annealing step, hydrogen is completely removed from silicon donor wafer and the exfoliation layer. The Si film on SiOG substrates 100 obtained this way has electrical properties that are close to electrical properties of the bulk silicon tiles from which the film was delaminated. The furnace is cooled down, and SiOG substrates and the remaining portions of the donor leftover tiles are unloaded from the furnace.

According to one embodiment hereof, anodic bonding may be employed. In the case of anodic bonding, a voltage potential (as indicated by the arrows and the + and − in FIG. 3) is applied across the intermediate assembly during the second heating step. For example a positive electrode is placed in contact with the semiconductor donor wafer 120 and a negative electrode is placed in contact with the glass substrate 102. The application of a voltage potential across the stack at the elevated bonding temperature during the second heating step induces alkali, alkaline earth ions or alkali metal ions (modifier ions) in the glass substrate 102 adjacent to the donor wafer 120 to move away from the semiconductor/glass interface further into the glass substrate 102. More particularly, positive ions of the glass substrate 102, including substantially all modifier ions, migrate away from the higher voltage potential of the semiconductor donor wafer 120, forming: (1) a reduced (or relatively low as compared to the original glass 136/102) positive ion concentration layer 132 in the glass substrate 102 adjacent the exfoliation layer 122; (2) an enhanced (or relatively high as compared to the original glass 136/102) positive ion concentration layer 134 in the glass substrate 102 adjacent the reduced positive ion concentration layer; while leaving (3) a remaining portion 136 of the glass substrate 102 with an unchanged ion concentration (e.g. the ion concentration of remaining layer 136 is the same as the original “bulk glass” substrate 102). The reduced positive ion concentration layer 132 in the glass support substrate performs a barrier function by preventing positive ion migration from the oxide glass or oxide glass-ceramic into the exfoliation layer 122.

With reference now to FIG. 4, after the intermediate assembly is held under the conditions of temperature, pressure and voltage for a sufficient time (such as about an hour), the voltage is removed and the intermediate assembly is allowed to cool to room temperature. The remaining portion 124 of the donor wafer 120 is removed from the exfoliation layer 122, leaving the exfoliation layer bonded to the glass substrate 102. The result is an SOG structure or substrate 100, e.g. a glass substrate 102 with the relatively thin exfoliation layer or film 122 of semiconductor material bonded to the glass substrate 102.

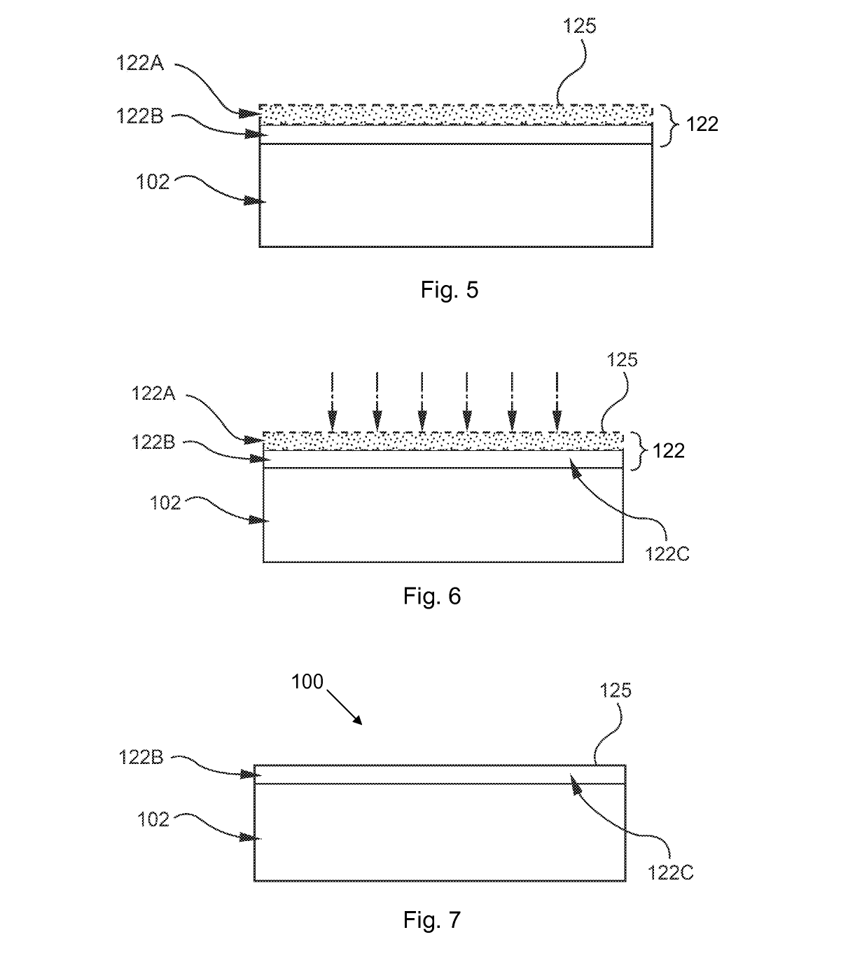

As illustrated in FIG. 5, after separation of the exfoliation layer 122 from the remaining portion 124 of the donor wafer, the resulting SOG structure 100 includes the glass substrate 102 and the exfoliation layer 122 of semiconductor material bonded thereto. The as transferred cleaved or exfoliated surface 125 of the SOI structure, just after exfoliation, typically exhibits excessive surface roughness as schematically illustrated by the dashed line 125 in FIGS. 4-6, and excessive silicon layer thickness. The as transferred exfoliation layer 122 of the intermediate structure includes two layers 122A, 122B. A first rough, damaged portion or layer 122A, closest to the rough cleaved surface 125, that includes implantation-induce and separation-induced defects and damage resulting from the ion implantation and layer transfer/exfoliation process as previously described, which damage extends to a first damaged depth below the surface of the as transferred silicon layer 122. A second undamaged portion or layer 122B, below the damaged portion 122A, is substantially free from any implantation-induced defects. The highest concentration of defects within the first layer 122A is expected nearest to the as transferred, exfoliated surface 125.

Transmission electron microscopy (TEM) analysis of a damaged layer 122A of the as transferred Si exfoliation layer or film 122 obtained in a thin film transfer process using a single hydrogen implant at energy 30 keV reveals that the damaged layer 122A has a thickness within a range from about 20 nm to about 100 nm thick, such as a thickness of about a 70 nm. The damage layer 122A will be thicker if hydrogen implantation energy is higher and thinner if the implantation energy is lower. The damaged layer 122A will be thinner when helium ion and hydrogen ion co-implantation techniques are employed than when just hydrogen ion implantation is employed. A thickness of the damaged layer 122A formed with co-implantation of hydrogen ions and helium ions typically falls into a range of from about 10 nm to about 20 nm thick. The surface of the as-transferred film typically has significant roughness, for example a roughness of about 10 nm RMS, as can be verified using atomic force microscopy (AFM). The surface roughness can be lower or higher then 10 nm, depending on film transfer process conditions, but it is typically undesirably high for effective further semiconductor device fabrication on the SOG structure 100.

With reference now to FIG. 6, according to an embodiment hereof, the rough, surface 125 of the as transferred exfoliated layer/film 122 is treated with oxygen plasma. The oxygen plasma treatment oxidizes the near surface region of the damaged layer 122A of the as transferred layer 122 and converts it to a sacrificial SiO₂ layer. The plasma oxidation process can be performed in a reactive ion etch (RIE) type plasma etching setup. In this type of a tool, the SOG substrate is plasma oxidized while the SOG substrate remains near-room temperature. This is beneficial for SiOG substrates, as there is no thermally-induced stress in the SOG substrate. Optionally, the plasma oxidation can be performed using PECVD tools, which can produce a controlled heating of the processed substrates. With PECVD tools, plasma oxidation can be performed at elevated temperatures, while only heating the glass substrate up to a temperature that glass material can withstand, e.g. up to about 600° C. Plasma oxidation at elevated temperatures allows for faster oxide growth and increased throughput. RF, microwave, and other types of plasma equipment and processes can be employed as well. Through routine experimentation, one skilled in the art can select proper plasma equipment and conditions, such as plasma power, processing time, oxygen flow, and pressure in the chamber, required to convert the desired thicknesses of the Si or semiconductor exfoliation layer into a silicon oxide layer of a sufficient depth or thickness for removal of the entire damaged layer 122A.

The finishing process in accordance with an embodiment hereof may include subjecting the as transferred surface 125 of the silicon exfoliation layer 122 to an oxygen plasma treatment process sufficient to oxidize the near surface region of the exfoliation layer to that is at least coextensive with or below the first damaged layer 122A of the exfoliation layer 122, thereby converting the entire damaged layer 122A of the as transferred semiconductor exfoliation layer 122 into a sacrificial oxide layer 122A. Thereafter, the sacrificial oxide layer, and therefore the entire previously damaged Si layer 122A, is stripped by bathing the SOG substrate 100 in a hydrofluoric acid (HF) or other suitable acid or etching solution as illustrated in FIG. 7. The damaged layer 122A is thus effectively removed from the surface 125 of the exfoliation layer 125 in a single oxygen plasma oxidation treatment and oxide layer strip cycle. The underlying Si layer 122B acts as an etch stop for halting the removal of material at the correct depth, e.g. at the surface of the Si layer 122B.

One skilled in the art can also properly choose suitable HF concentrations, or other acid or etchant concentrations in the bath, and etching time. After the oxide stripping, the SiOG substrate is cleaned and the process is complete. The processed SiOG substrate has no damaged portion of the silicon film and the roughness of the transferred silicon film surface is improved. AFM analysis of the processed SiOG substrate showed that both, RMS roughness and peak-to-valley roughness improved.

Removal of the entire damaged layer 122A in a single plasma oxidation and strip cycle may only be achievable in the case of co-implantation of H and He ions. Co-implantation of H and He ions produces a damaged layer 122A having a depth in a range from about 10 nm to about 20 nm. Plasma processing conditions may be chosen such that a thickness or depth of the oxidized SiO₂ layer is equal to or slightly greater than the thickness of the damaged layer 122A of the as transferred silicon film, i.e. equal to or greater than from about 10 nm to about 20 nm thick, such that the entire damaged layer 122A is oxidized in a single plasma oxidation step. To determine the right thickness to be oxidized, the thickness of the damaged silicon may first be measured using an appropriate technique, for example, with a transmission electron microscope.

In order to convert the entire depth of the damaged layer 122A into a SiO₂ sacrificial layer 148, the exfoliation surface 125 of the SOG substrate 100 may be processed in a low frequency plasma. According to an embodiment hereof, in order for the oxygen plasma treatment to oxidize and convert the damaged surface of the exfoliation to a depth of about 10 nm to about 20 nm thick, (as is require to completely remove the damaged layer) the oxygen plasma is generated at a relatively low frequency in the kHz range. In order to achieve this depth of oxidation, the oxygen plasma may be generated at a frequency of 1 MHz or lower, from 1 kHz to 1 MHz, at about 13.56 MHz, or at about 30 kHz. However, only some frequencies within this range may be allowed by law, depending on where the oxygen plasma treatment is being performed. In the United States for example, only 13.56 MHz plasma may be legally employed in the MHz range and in the low frequency kHz range (i.e., low frequencies) 30 kHz is one of several allowed frequencies. DC plasma, i.e. zero frequency plasma, is also permissible in the United States. The plasma may be generated using a power in a range from about 1 Watt/cm² to about 50 Watts/cm² at a pressure in a range of from about 0.3 mTorr to about 300 mTorr, for a time of about 0.5 minutes to about 50 minutes. One of skill in the art will understand how to select safe and legal frequencies for plasma generation.

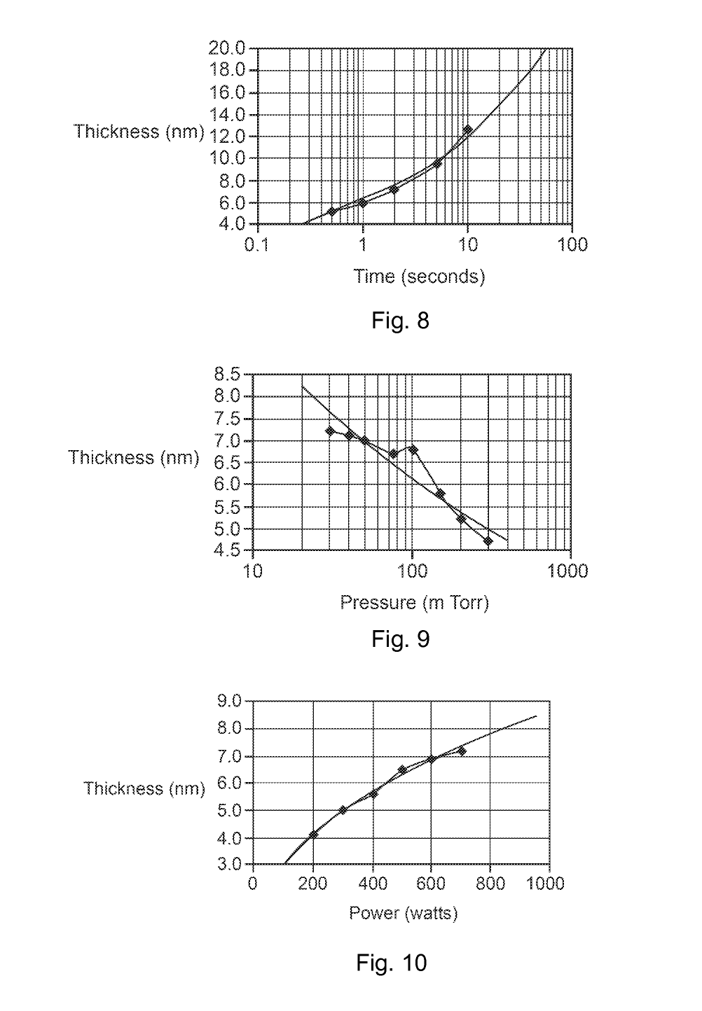

One skilled in the art can properly choose the proper plasma conditions for oxidizing/converting the as transferred surface 125 of the exfoliation layer 122 to the proper depth may be chosen using calibration curves similar to ones shown in FIG. 8 through FIG. 10. FIGS. 8 through 10 show calibration curves for the thickness of the converted oxide layer in the surface of a silicon film as a function of three main plasma processing parameters. FIG. 8 is a calibration curve for the thickness in nanometers of the converted/oxidized layer obtained in the surface of an as-exfoliated silicon film as a function plasma processing time in seconds. FIG. 8 shows that the thickness in nanometers of the oxidized layer in a silicon film monotonically increases with plasma processing time. FIG. 9 and FIG. 10 are similar calibration curves for the thickness of the oxidized layer as a function of plasma pressure and as a function of plasma power, respectively, in the plasma chamber. The calibration curves in FIGS. 8 through 10 were obtained using a plasma tool having 30 kHz plasma generator. For plasma tools having a different type of excitation, such as DC generators, 13.56 MHz generators, or microwave generators, the proper calibration curves can be easily obtained by one skilled in the art.

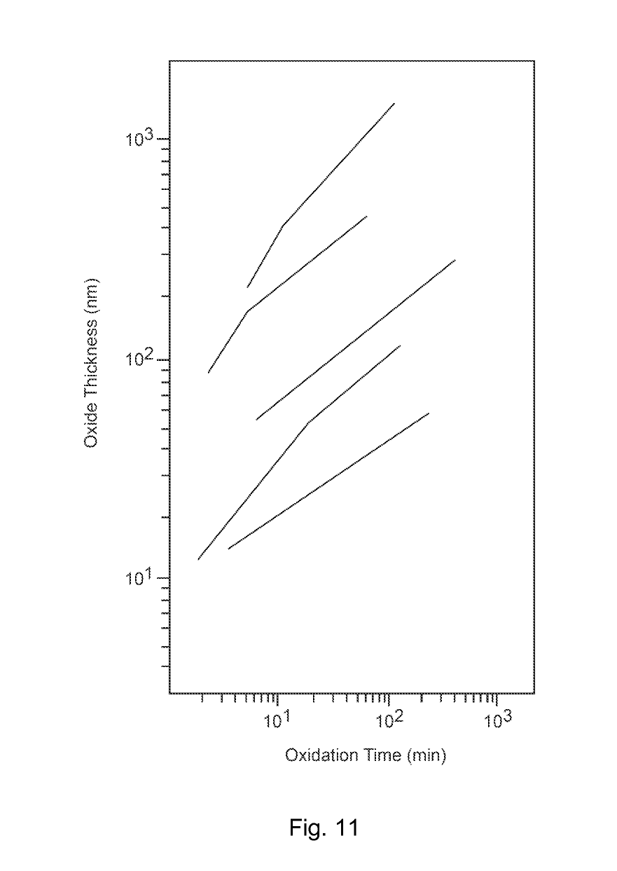

FIG. 11 is a plot illustrating the oxidation growth kinetics in a process in accordance with an embodiment hereof. FIG. 11 plots oxide thickness against processing time in the plasma, as described in a review of the plasma oxidation of silicon and its applications, Semicond. Sci. Technol. 8, by S Taylor, J F Zhang and W Eccleston, (1993) 1426-1433. As can be seen from the FIG. 1, oxidized layer thicknesses from 10 nm to 1 micron can be obtained by plasma oxidation. A thickness of the damaged portion 122A of the as transferred silicon film typically falls into a range from 10 nm to 100 nm. As illustrated by the plot in FIG. 11, there are plasma processing conditions that are capable complete oxidizing of the damaged portion 122A of the typical as transferred silicon film.

A thickness of the damaged portion or layer 122A on the surface of the transferred silicon film 122 formed during implantation of hydrogen ions only typically has a thickness in a range from 20 nm to 100 nm. In some instances, plasma processing conditions may not be obtainable that allow for complete oxidizing of a damaged portion 122A of the silicon film of this thickness. According to another embodiment hereof, a first portion of the damaged layer 122A may be oxidized in a first plasma oxidation step. The first oxidized portion of the damaged layer 122A is then stripped as described above, in a first stripping step completing a first plasma oxidation and strip cycle. A remaining or second portion of the damaged layer 122A may then be oxidized in a second plasma oxidation step. The remaining or second oxidized portion of the damaged layer 122A is then stripped in a second stripping step as described above, completing a second plasma oxidation and strip cycle that completely removes the remaining portion of the damaged layer 122A, leaving just a smooth, finished undamaged Si layer 122B as illustrated in FIG. 7. It will be appreciated that 3 or more plasma oxidation and strip cycles may be employed to remove the entire damaged layer if required. However, as the number of required cycles increases, the process as described herein may begin to lose its advantages over other available layer removal and smoothening techniques.

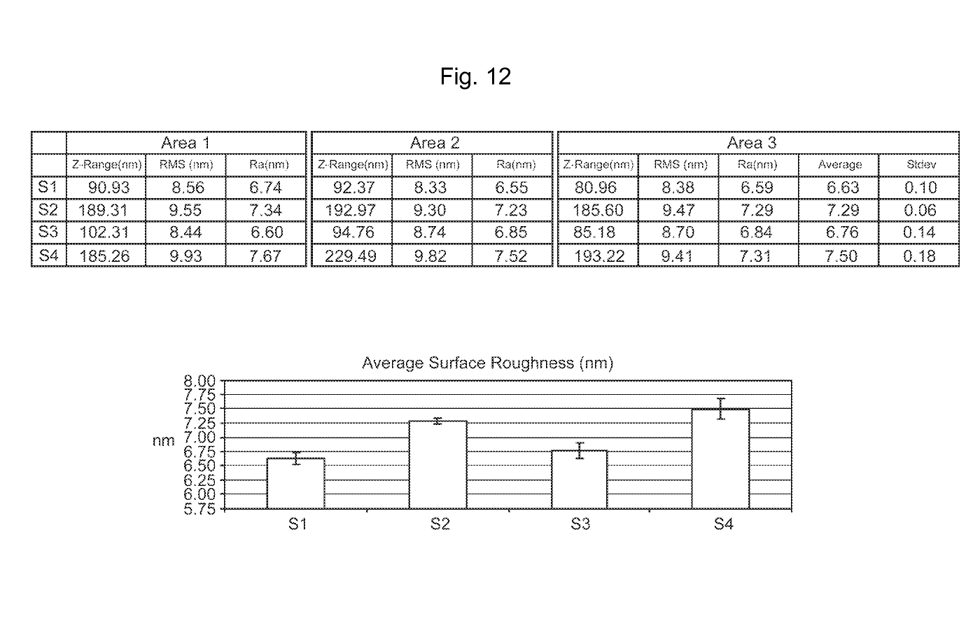

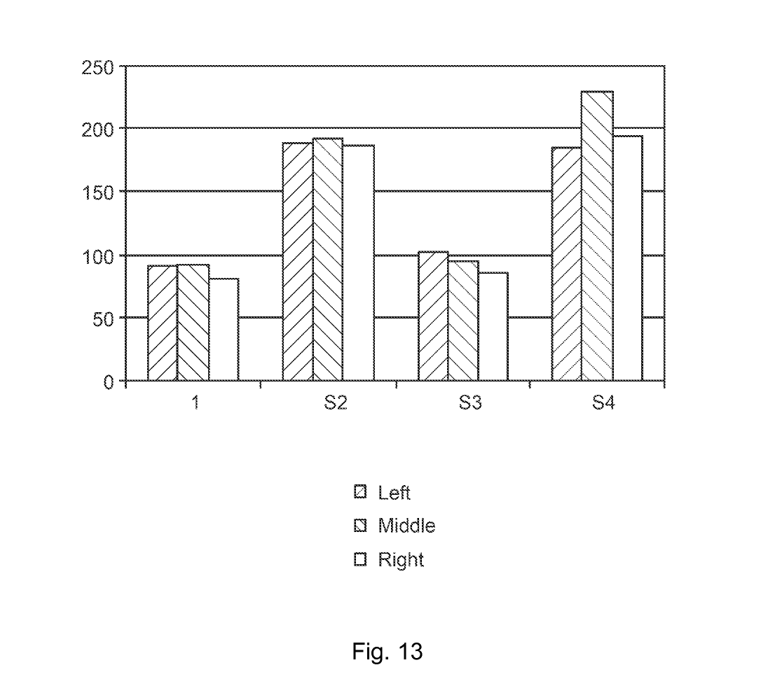

FIGS. 12 and 13 are plots showing the average surface roughness of the as transferred surface of various test samples before and after processing in accordance with an embodiment hereof in comparison to a control sample. Sample S1, the as transferred surface was oxidized using an oxygen plasma treatment in a PECVD #201800 machine at 20 mTorr and 650 watts for 70 minutes and the oxidized layer stripped as described herein. Sample S2 is a control sample with an untreated as transferred surface. Sample S3, the as transferred surface was oxidized using an oxygen plasma treatment in a LPCVD #201798 machine at 20 mTorr and 650 watts for 70 minutes. Sample S4 is a control sample with an untreated as transferred surface. As can be seen in FIG. 12, the surface roughness was improved using the oxygen plasma oxidation and stripping process as described herein. FIG. 13 is a plot showing peak-to-valley surface roughness of the as transferred surface of various test samples.

Compared to prior art techniques of addressing the implantation and separation damage problem, the embodiments of the present invention are less expensive to implement and are relatively straight forward and simple. For example, prior art polishing techniques typically require at least one hour per square foot of polishing time, resulting in only a 50 nm or less material removal. In contrast, the techniques of one or more embodiments of the present invention require a few minutes in a plasma chamber followed by an acid strip. Moreover, compared to the prior art polishing technique, the one or more methods of the present invention result in higher quality final products. Indeed, mechanical polishing processes typically result in degradation of thickness uniformity of the exfoliation layer 122, while the process disclosed herein does not. This advantage is more pronounced for very thin exfoliation layers of about 100 nanometers and less. Moreover, oxidation of silicon is an isotropic process. As a result, the interface between transferred silicon 122 and the oxidized layer 122A is much smoother compared to the surface of the as-transferred silicon film, thereby producing a smoother surface when the oxide layer is stripped. After the plasma oxidation and stripping cycles as disclosed herein, the silicon film in the SiOG has no damaged portions, and it has a smoother, finished surface. Both plasma processing and HF strip are routine manufacturing processes that can be easily adopted by those skilled in the art and scaled up for volume manufacturing. Also, the plasma oxidation and wet HF strip may both be room temperature processes, which is beneficial for use with SiOG substrates that cannot tolerate high temperatures.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of forming a semiconductor on glass structure, comprising:
subjecting an implantation surface of a semiconductor donor wafer to an ion implantation process to create an exfoliation layer of the semiconductor donor wafer;
bonding the implantation surface of the exfoliation layer to a glass substrate;
separating the exfoliation layer from the semiconductor donor wafer, thereby exposing an ion implantation damaged layer on the surface of the exfoliation layer;
the subjecting the exposed damaged layer to oxygen plasma to oxidize the exposed damaged layer and convert at least a portion of the exposed damaged layer to an oxide layer; and
stripping the oxide layer, thereby removing at least a portion of the damaged layer.

2. The method of claim 1, wherein the oxygen plasma processing parameters are in a range sufficient to oxidize at least a portion of the exposed damaged layer, while leaving at least a portion of an undamaged lower portion of the semiconductor exfoliation layer unoxidized.

3. The method of claim 2, wherein the oxygen plasma processing parameters are in a range sufficient to oxidize the exposed damaged layer to a depth that is at least equal to or slightly greater than a depth of the damaged layer.

4. The method of claim 3, wherein the oxygen plasma processing parameters are selected to oxidize the exposed damaged layer to a depth in a range from about 10 nm to about 20 nm.

5. The process of claim 3, wherein the plasma treatment is conducted in a plasma generated at a frequency of 1 MHz or lower.

6. The process of claim 5, wherein the plasma treatment is conducted in a plasma generate at a frequency of from 1 MHz to 1 kHz, or about 30 kHz or lower.

7. The process of claim 5, wherein the plasma treatment is conducted in a plasma generate at a frequency of 13.56 MHz, or 30 kHz.

8. The process of claim 5, wherein the plasma treatment is conducted in a direct current plasma (zero frequency) with at least one of:
a power in a range from about 1 Watt/cm² to about 50 Watts/cm²;
a pressure in a range from about 0.3 mTorr to about 300 mTorr; and
for a time in a range from about 0.5 minutes to about 50 minutes.

9. The method of claim 1, wherein the semiconductor donor wafer is taken from the group consisting of: gallium nitride (GaN), silicon (Si), germanium-doped silicon (SiGe), silicon carbide (SiC), germanium (Ge), gallium arsenide (GaAs), GaP, and InP.

10. The method of claim 1, wherein a portion of the damaged layer remains on the exfoliation layer following oxygen plasma oxidizing and stripping steps, and further comprising the steps of:
the subjecting the remaining portion of the damaged layer to oxygen plasma to oxidize the remaining portion of the damaged layer and convert at least a portion of the remaining portion of the exposed damaged layer to an oxide layer; and
stripping the oxide layer, thereby removing at least a portion of the remaining portion of the damaged layer.

11. The method of claim 10, wherein the oxygen plasma processing parameters when oxidizing the remaining portion of the damaged layer are in a range sufficient to oxidize the remaining portion of the damaged layer to a depth that is at least equal to or slightly greater than a depth of the remaining portion of the damaged layer.

12. A method of forming a semiconductor on glass structure, comprising: providing a semiconductor donor structure having weakened damaged layer therein defining an exfoliation layer between the damaged layer and a bonding surface of the donor wafer;
bonding the bonding surface of the donor semiconductor structure to an insulating support substrate;
separating the exfoliation layer, bonded to the support substrate, from the donor semiconductor structure along the damaged layer, thereby exposing a damaged surface on the exfoliation layer, the damaged surface including damage to a first depth below the damaged surface;
subjecting the at least one damaged surface to an oxygen plasma treatment to oxidize the damages surface to at least a second depth of the semiconductor material; and
removing the oxide layer, thereby removing the damaged layer from the semiconductor layer.

13. The method of claim 12, wherein the oxygen plasma parameters are in a range sufficient to oxidize the exposed damaged layer to a depth that is at least equal to or slightly greater than the second depth.

14. The method of claim 12, wherein the oxygen plasma processing parameters are selected to oxidize the exposed damaged layer to a depth in a range from about 10 nm to about 20 nm.

15. The process of claim 12, wherein the plasma treatment is conducted in a plasma generated at a frequency of 1 MHz or lower.

16. The process of claim 15, wherein the plasma treatment is conducted in a plasma generate at a frequency of from 1 MHz to 1 kHz, or about 30 kHz or lower.

17. The process of claim 16, wherein the plasma treatment is conducted in a plasma generate at a frequency of 13.56 MHz, or 30 kHz.

18. The process of claim 15, wherein the plasma treatment is conducted in a direct current plasma (zero frequency) with at least one of:
a power in a range from about 1 Watt/cm² to about 50 Watts/cm²;
a pressure in a range from about 0.3 mTorr to about 300 mTorr; and
for a time in a range from about 0.5 minutes to about 50 minutes.

19. The process of claim 12, wherein the insulating support substrate is a glass or glass-ceramic substrate.
